(19) United States
(12) Patent Application Publication
(10) Pub. No.: US 2023/0054199 A1
(43) Pub. Date: Feb. 23, 2023

(54) CMP POLISHING LIQUID AND POLISHING METHOD

(71) Applicant: Showa Denko Materials Co., Ltd., Tokyo (JP)

(72) Inventors: Shingo KOBAYASHI, Tokyo (JP); Hisataka MINAMI, Tokyo (JP); Yuya OTSUKA, Tokyo (JP); Mayumi KOMINE, Tokyo (JP); Jenna WU, Tokyo (JP); Hisato TAKAHASHI, Tokyo (JP)

(21) Appl. No.: 17/797,333

(22) PCT Filed: Feb. 12, 2021
(86) PCT No.: PCT/JP2021/005328

§ 371 Date: Aug. 3, 2022

(30) Foreign Application Priority Data
Feb. 13, 2020 (WO) PCT/JP2020/005602
May 14, 2020 (JP) 2020-085178

(51) Int. Cl. C09G 1/02

(52) U.S. Cl. CPC C09G 1/02

(57) ABSTRACT

An aspect of the present disclosure provides a CMP polishing liquid containing: abrasive grains; and a cationic polymer, in which the cationic polymer has a main chain containing a nitrogen atom and a carbon atom and a hydroxyl group bonded to the carbon atom. The CMP polishing liquid may further contain at least one cyclic compound selected from the group consisting of an amino group-containing aromatic compound and a nitrogen-containing heterocyclic compound. Another aspect of the present disclosure provides a polishing method including a step of polishing a material to be polished by using this CMP polishing liquid.

### TECHNICAL FIELD

The present disclosure relates to a CMP polishing liquid, a polishing method, and the like.

### BACKGROUND ART

In the field of semiconductor production, with achievement of high performance of memory devices (ultra LSI devices and the like), a miniaturization technology as an extension of the conventional technology finds restriction in allowing high integration and speed-up to be compatible with each other. Accordingly, while miniaturization of semiconductor elements is being promoted, techniques for allowing vertical high integration (namely, techniques for developing multilayered wiring, elements, and the like) have been developed.

In the process for producing a device including multilayered wiring, elements, and the like, one of the most important techniques is a CMP (chemical mechanical polishing) technique. The CMP technique is a technique in which a thin film is formed on a substrate by chemical vapor deposition (CVD) or the like to obtain a base substrate, and then the surface of this base substrate is flattened. When the surface of the base substrate after being flattened has irregularities, there occur, for example, such troubles that the focusing in an exposure step is precluded, or a fine wiring structure cannot be sufficiently formed. The CMP technique is also applied, in a production process of a device, to a step of forming an element isolation region by polishing a plasma oxide film (such as BPSG, HDP-SiO₂, or p-TEOS), a step of forming an interlayer insulating film, a step of flattening a plug (for example, Al·Cu plug) after a silicon oxide film (a film containing silicon oxide) is embedded in a metal wiring, or the like.

CMP is usually performed using an apparatus capable of supplying a polishing liquid onto a polishing pad. The surface of a base substrate is polished by pressing the base substrate against the polishing pad while the polishing liquid is supplied between the surface of the base substrate and the polishing pad. In the CMP technique, a high-performance polishing liquid is one of elemental technologies and various polishing liquids have also been hitherto developed (see, for example, Patent Literature 1 below).

### CITATION LIST

### Patent Literature

Patent Literature 1: Japanese Unexamined Patent Publication No. 2013-175731

### SUMMARY OF INVENTION

### Technical Problem

Incidentally, in the step of forming an element isolation region on the substrate, a material to be polished (for example, an insulating material such as silicon oxide) is formed by CVD or the like so as to fill irregularities having been provided in advance on the surface of the substrate. Thereafter, the surface of the material to be polished is flattened by CMP to form an element isolation region. In a case where the material to be polished is formed on the substrate of which irregularities for obtaining an element isolation region are provided on the surface, irregularities corresponding to the irregularities of the substrate are also generated on the surface of the material to be polished. In the polishing of the surface having irregularities, while a convex portion is preferentially removed, a concave portion is slowly removed so as to flatten the surface.

In order to improve a process margin and a yield of semiconductor production, it is preferable to remove an unnecessary portion of the material to be polished, which has been formed on the substrate, uniformly and rapidly in the plane of the base substrate as much as possible. For example, in the case of adopting shallow trench isolation (STI) in order to respond to the achievement of the narrow width of the element isolation region, it is required to remove the step height and the unnecessary portion of the material to be polished provided on the substrate at a high polishing rate.

Generally, improvement in production efficiency is achieved by dividing the polishing treatment of the material to be polished into two stages in some cases. In the first step (rough polishing), most of the step height of the material to be polished is removed, and in the second step (finishing step), the material to be polished is slowly finished so as to be adjusted to an arbitrary thickness and to sufficiently flatten the surface to be polished.

In a case where CMP with respect to a material to be polished is divided into two or more stages as described above, in the second step, it is necessary to suppress dishing to the minimum and to sufficiently flatten a surface to be polished. However, in a conventional CMP polishing liquid, there is a room for improvement in achievement of both of high step height removability (performance of removing step height) attributable to a high polishing rate for a material to be polished (such as an insulating material) and high flatness after the step height is removed.

An aspect of the present disclosure is intended to solve the above-described problems and an object thereof is to provide a CMP polishing liquid having a large difference between a polishing rate at the time of a high load and a polishing rate at the time of a low load (showing the non-linear load dependency of the polishing rate). Furthermore, an object of another aspect of the present disclosure is to provide a polishing method using the above-described CMP polishing liquid.

### Solution to Problem

The present inventors have focused on that a large difference between a polishing rate at the time of a high load and a polishing rate at the time of a low load (showing the non-linear load dependency of the polishing rate) is effective for achieving both of high step height removability and high flatness. In a case where the step height in the surface of a base substrate having irregularities is high at the initial stage of polishing the base substrate, a polishing pad contacts mainly with a convex portion, and thus a load per unit area of a contact part of the surface to be polished with the polishing pad is high. In this case, when a polishing liquid with which a high polishing rate is obtainable at the time of a high load is used, removal of the convex portion is easy to proceed so as to obtain high step height removability. On the other hand, in a case where polishing of the base substrate sufficiently proceeds and the step height in the surface of the base substrate is low, the polishing pad also easily contacts with the concave portion in addition to the convex portion, and thus a load per unit area of the contact part of the surface to be polished with the polishing pad is low. In this case, when a polishing liquid with which a low polishing rate is obtainable at the time of a low load is used, removal of the concave portion is difficult to proceed so as to obtain high flatness.

Further, the present inventors have conducted intensive studies on additives blended in a CMP polishing liquid from the viewpoint of obtaining a CMP polishing liquid showing the non-linear load dependency of the polishing rate. The present inventors have prepared many CMP polishing liquids by using various compounds as additives. Base substrates having irregularities were polished using these CMP polishing liquids and the polishing rates at the time of a high load and at the time of a low load were evaluated. As a result, it has been found that it is effective to use a cationic polymer having a main chain containing a nitrogen atom and a carbon atom and a hydroxyl group bonded to the carbon atom for obtaining the non-linear load dependency of the polishing rate.

An aspect of the present disclosure provides a CMP polishing liquid containing: abrasive grains; and a cationic polymer, in which the cationic polymer has a main chain containing a nitrogen atom and a carbon atom and a hydroxyl group bonded to the carbon atom.

Another aspect of the present disclosure provides a polishing method including a step of polishing a surface to be polished by using the aforementioned CMP polishing liquid.

According to the CMP polishing liquid and the polishing method as described above, a difference between a polishing rate at the time of a high load and a polishing rate at the time of a low load can be increased (the non-linear load dependency of the polishing rate can be obtained), and both of high step height removability and high flatness can be achieved when a base substrate having irregularities is polished.

### Advantageous Effects of Invention

According to an aspect of the present disclosure, it is possible to provide a CMP polishing liquid having a large difference between a polishing rate at the time of a high load and a polishing rate at the time of a low load (showing the non-linear load dependency of the polishing rate). Furthermore, according to another aspect of the present disclosure, it is possible to provide a polishing method using the above-described CMP polishing liquid. These CMP polishing liquid and polishing method can be used for polishing an insulating material (for example, silicon oxide) provided on a surface of a base substrate (for example, a semiconductor wafer).

### BRIEF DESCRIPTION OF DRAWINGS

FIG. 1 is a schematic cross-sectional view illustrating a process in which a silicon oxide film is polished to form an STI structure.

FIG. 2 is a schematic cross-sectional view illustrating a process in which a material to be polished having irregularities is polished to eliminate the irregularities.

FIG. 3 is a schematic cross-sectional view illustrating a process in which a material to be polished having irregularities is polished to eliminate the irregularities.

FIG. 4 is a schematic cross-sectional view illustrating a process in which a material to be polished having irregularities is polished to eliminate the irregularities.

### DESCRIPTION OF EMBODIMENTS

Hereinafter, an embodiment of the present disclosure will be described in detail. However, the present disclosure is not limited to the following embodiment and can be modified variously within the scope of the spirit thereof and carried out.

In the present specification, a numerical range that has been indicated by use of “to” indicates the range that includes the numerical values which are described before and after “to”, as the minimum value and the maximum value, respectively. In the numerical ranges that are described stepwise in the present specification, the upper limit value or the lower limit value of the numerical range of a certain stage can be arbitrarily combined with the upper limit value or the lower limit value of the numerical range of another stage. In the numerical ranges that are described in the present specification, the upper limit value or the lower limit value of the numerical value range may be replaced with the value shown in Examples. “A or B” may include either one of A and B, and may also include both of A and B. Materials listed as examples in the present specification can be used singly or in combinations of two or more, unless otherwise specifically indicated. In the present specification, when a plurality of substances corresponding to each component exist in the composition, the used amount of each component in the composition means the total amount of the plurality of substances that exist in the composition, unless otherwise specified. Furthermore, in the present specification, the term “film” includes a structure having a shape which is formed on a part, in addition to a structure having a shape which is formed on the whole surface, when the film has been observed as a plan view. Furthermore, in the present specification, the term “step” includes not only an independent step but also a step by which an intended action of the step is achieved, even though the step cannot be clearly distinguished from other steps.

### CMP Polishing Liquid

A CMP polishing liquid (polishing liquid for CMP) of the present embodiment contains abrasive grains (polishing particles) and a cationic polymer, and the cationic polymer has a main chain containing a nitrogen atom (N atom) and a carbon atom (C atom) and a hydroxyl group bonded to the carbon atom.

According to the CMP polishing liquid of the present embodiment, the non-linear load dependency of the polishing rate can be obtained, and both of high step height removability and high flatness can be achieved when a base substrate having irregularities (for example, a base substrate having an insulating material such as silicon oxide on the surface thereof) is polished. According to the CMP polishing liquid of the present embodiment, a large difference in polishing rate between a time when a high load is applied and a time when a low load is applied can be achieved, and for example, a large difference in polishing rate between a time when a load of 4.0 psi is applied and a time when a load of 3.0 psi is applied can be achieved. It is speculated that, as a load is lower, the cationic polymer having a main chain containing a nitrogen atom and a carbon atom and a hydroxyl group bonded to the carbon atom adsorbs to a portion of a material to be polished in contact with a polishing pad such that the portion is protected, and thereby the non-linear load dependency of the polishing rate is obtainable.

Generally, improvement in production efficiency is achieved by dividing the polishing treatment of the material to be polished into two stages in some cases. In the first step (rough polishing), most of the step height of the material to be polished is removed, and in the second step (finishing step), the material to be polished is slowly finished so as to be adjusted to an arbitrary thickness and to sufficiently flatten the surface to be polished. That is, in the first step, a material to be polished having irregularities is polished; on the other hand, in the second step, a material to be polished having very small irregularities and substantially not having irregularities is polished. In the first step, in order to rapidly eliminate irregularities of a material to be polished having irregularities, it is required to achieve a high polishing rate for a material to be polished having irregularities.

Furthermore, according to the findings of the present inventors, it is speculated that, in a case where a polishing rate ratio of a material to be polished having irregularities with respect to a material to be polished not having irregularities is high, flatness is further improved when the material to be polished having irregularities is polished to eliminate the irregularities. Further, in the case of using silicon oxide as a material to be polished, it is required to obtain such a polishing rate ratio corresponding to presence and absence of irregularities.

The present inventors have conducted intensive studies on an additive to be blended in the CMP polishing liquid. The present inventors have prepared many CMP polishing liquids by using various compounds as additives. The dependency of the polishing rate with respect to presence and absence of irregularities was evaluated by polishing silicon oxide having irregularities and silicon oxide not having irregularities by using these CMP polishing liquids. As a result, it has been found that use of a specific additive is effective.

Embodiment A that is an embodiment of the present embodiment provides a CMP polishing liquid containing: abrasive grains; a cationic polymer; and at least one cyclic compound selected from the group consisting of an amino group-containing aromatic compound and a nitrogen-containing heterocyclic compound, in which the cationic polymer has a main chain containing a nitrogen atom and a carbon atom and a hydroxyl group bonded to the carbon atom.

According to the CMP polishing liquid of Embodiment A, a high polishing rate ratio of a material to be polished having irregularities with respect to a material to be polished not having irregularities (the polishing rate for a material to be polished having irregularities/the polishing rate for a material to be polished not having irregularities; hereinafter, simply referred to as “polishing rate ratio”) can be achieved while a high polishing rate for a material to be polished having irregularities is achieved, and particularly, a high polishing rate ratio of an insulating material (such as silicon oxide) having irregularities with respect to an insulating material (such as silicon oxide) not having irregularities can be achieved while a high polishing rate for an insulating material (such as silicon oxide) having irregularities is achieved. According to such a CMP polishing liquid, since a high polishing rate ratio of a material to be polished having irregularities with respect to a material to be polished not having irregularities can be achieved, flatness can be further improved when the material to be polished having irregularities is polished to eliminate the irregularities. According to the CMP polishing liquid of Embodiment A, both of high step height removability and a high polishing rate ratio can be achieved.

Although a factor responsible for these effects is not necessarily clear, the factor is presumed as described below.

That is, the cationic polymer having the aforementioned specific structure can be adsorbed to a material to be polished (for example, an insulating material such as silicon oxide); at a portion to which a load is strongly applied, the cationic polymer is easily removed by friction during polishing; on the other hand, at a portion to which a load is unlikely to be strongly applied, the cationic polymer is not removed but protects the adsorption part. Therefore, in the case of polishing a material to be polished having irregularities, since a load is strongly applied to the convex portion that is a main object to be polished, the cationic polymer is removed and polishing proceeds, and thus a high polishing rate for the convex portion is obtained. On the other hand, in the case of polishing a material to be polished not having irregularities, since a load is dispersed on the entire surface to be polished, the load is unlikely to be applied to the material to be polished. Therefore, since the cationic polymer is not removed but protects the adsorption part, polishing is difficult to proceed, and thus a high polishing rate is difficult to be obtainable.

Furthermore, in polishing of a material to be polished having irregularities (for example, an insulating material such as silicon oxide), as mentioned above, a high polishing rate for the convex portion is obtained; on the other hand, in the concave portion to which a load is unlikely to be applied, the concave portion is protected without removing the cationic polymer, and thus polishing is difficult to proceed. Therefore, the convex portion is preferentially polished to be removed with respect to the concave portion.

Further, the cyclic compound having the aforementioned specific structure is adsorbed to the abrasive grains due to the nitrogen atom in the cyclic compound, and thereby the reaction activity of the abrasive grains with respect to a material to be polished (for example, an insulating material such as silicon oxide) can be enhanced. Therefore, in the case of polishing a material to be polished having irregularities, a polishing rate for the convex portion to which a load is strongly applied and which is difficult to be protected by the cationic polymer is easily increased.

According to these actions, both of high step height removability and a high polishing rate ratio can be achieved.

Generally, in the two-stage polishing treatment of the aforementioned first step (rough polishing) and second step (finishing step), a polishing liquid is changed between the first step and the second step in some cases; however, according to the CMP polishing liquid of the aforementioned Embodiment A, polishing in both of the first step and the second step can be performed, so that productivity and facility simplification can be achieved.

According to the CMP polishing liquid of the present embodiment, both of high step height removability and high flatness can be achieved without significantly depending on the shape of the surface of an object to be polished. Furthermore, according to the CMP polishing liquid of the present embodiment, since high step height removability can be obtained, a material to be polished (for example, an insulating material such as silicon oxide) provided on a substrate having irregularities can be suitably polished. Therefore, according to the CMP polishing liquid of the present embodiment, the effect can be exerted even for a base substrate (for example, a semiconductor material) in which removal of the step height is relatively difficult by a conventional CMP polishing liquid. For example, the effect can be exerted even in the case of polishing a material to be polished (for example, an insulating material such as silicon oxide) having a step height of 1 µm or more or a material to be polished (for example, an insulating material such as silicon oxide) having a portion with a concave portion or a convex portion in a T-shaped or lattice-shaped fashion when viewed from above, like a semiconductor substrate having a memory cell.

The CMP polishing liquid of the present embodiment may be a CMP polishing liquid that is used for polishing an insulating material. The CMP polishing liquid of the present embodiment can also be used in rough polishing of an insulating material. The insulating material may contain an inorganic insulating material and may contain silicon oxide. The CMP polishing liquid of the present embodiment may be a polishing liquid for polishing a material to be polished (for example, an insulating material such as silicon oxide) of a base substrate having the material to be polished on the surface thereof.

### Abrasive Grains

The abrasive grains can contain, for example, a cerium-based compound, alumina, silica, titania, zirconia, magnesia, mullite, silicon nitride, α-sialon, aluminum nitride, titanium nitride, silicon carbide, boron carbide, or the like. The constituent components of the abrasive grains can be used singly or in combination of two or more types thereof. The abrasive grains preferably contain a cerium-based compound from the viewpoint of easily obtaining the non-linear load dependency of the polishing rate and easily achieving both of high step height removability and high flatness with respect to a base substrate having irregularities (for example, a base substrate having an insulating material such as silicon oxide on the surface thereof) and the viewpoint of easily achieving both of high step height removability and a high polishing rate ratio.

The CMP polishing liquid using the abrasive grains containing a cerium-based compound has a feature that polishing scratches occurring on the polished surface are relatively small in number. From the viewpoint of easily achieving a high polishing rate of a material to be polished (for example, an insulating material such as silicon oxide), a CMP polishing liquid containing silica particles as the abrasive grains can be used. However, the CMP polishing liquid using silica particles generally has a problem in that polishing scratches easily occur on the polished surface. In a device having fine patterns since the generation of 45 nm in wire width, even fine scratches having hitherto caused no problems may affect the reliability of the device.

Examples of the cerium-based compound include cerium oxide, cerium hydroxide, cerium ammonium nitrate, cerium acetate, cerium sulfate hydrate, cerium bromate, cerium bromide, cerium chloride, cerium oxalate, cerium nitrate, and cerium carbonate. The cerium-based compound preferably contains cerium oxide. By using cerium oxide, the viewpoint of easily obtaining the non-linear load dependency of the polishing rate and easily achieving both of high step height removability and high flatness, the viewpoint of easily achieving both of high step height removability and a high polishing rate ratio, and a polished surface with less polishing scratches are easily obtained.

In the case of using cerium oxide, it is preferable that the abrasive grains contain polycrystalline cerium oxide having a crystal grain boundary (for example, polycrystalline cerium oxide having multiple crystallites surrounded by crystal grain boundaries). It is considered that the polycrystalline cerium oxide particle having such a configuration is different from a simple aggregate in which single crystal particles aggregate, is made fine by the stress during polishing, and at the same time allows active surfaces (the surfaces not exposed to outside before being made fine) to appear one after another, so that a high polishing rate of a material to be polished (for example, an insulating material such as silicon oxide) can be highly maintained. Such a polycrystalline cerium oxide particle is described in detail, for example, in International Publication WO 99/31195.

The method for producing abrasive grains containing cerium oxide is not particularly limited, and examples thereof include liquid phase synthesis; and a method performing oxidation by firing or hydrogen peroxide or the like. In the case of obtaining abrasive grains containing the above-described polycrystalline cerium oxide having a crystal grain boundary, a method in which a cerium source such as cerium carbonate is fired is preferred. The temperature during the above-described firing is preferably 350° C. to 900° C. In a case where the produced cerium oxide particles aggregate, it is preferable to mechanically pulverize. The pulverizing method is not particularly limited, but for example, dry pulverization with a jet mill or the like; and wet pulverization with a planetary bead mill or the like are preferred. The jet mill is described, for example, in “Kagaku Kogaku Ronbunshu (Chemical Industrial Paper Collection)”, Vol. 6, No. 5, 1980, pp. 527 to 532.

In a case where the abrasive grains contain a cerium-based compound (for example, cerium oxide), the content of the cerium-based compound in the abrasive grains is preferably 50% by mass or more, more preferably 70% by mass or more, further preferably 90% by mass or more, particularly preferably 95% by mass or more, extremely preferably 97% by mass or more, and highly preferably 99% by mass or more, on the basis of the whole of the abrasive grains (the whole of the abrasive grains contained in the CMP polishing liquid), from the viewpoint of easily obtaining a high polishing rate for a material to be polished (for example, an insulating material such as silicon oxide). The abrasive grains containing a cerium-based compound may be an embodiment which is substantially composed of a cerium-based compound (an embodiment in which substantially 100% by mass of the abrasive grains is a cerium-based compound).

The average particle diameter of the abrasive grains is preferably 50 nm or more, more preferably 70 nm or more, further preferably more than 70 nm, particularly preferably 75 nm or more, extremely preferably 80 nm or more, highly preferably 85 nm or more, and even more preferably 90 nm or more, from the viewpoint of easily obtaining a high polishing rate for a material to be polished (for example, an insulating material such as silicon oxide). The average particle diameter of the abrasive grains is preferably 500 nm or less, more preferably 300 nm or less, further preferably 280 nm or less, particularly preferably 250 nm or less, extremely preferably 200 nm or less, highly preferably 180 nm or less, even more preferably 160 nm or less, further preferably 150 nm or less, particularly preferably 120 nm or less, extremely preferably 100 nm or less, and highly preferably 90 nm or less, from the viewpoint of easily suppressing polishing scratches. From these viewpoints, the average particle diameter of the abrasive grains is preferably 50 to 500 nm.

In order to control the average particle diameter of the abrasive grains, conventionally known methods can be used. By taking the cerium oxide particles as an example, examples of the method of controlling the average particle diameter of the abrasive grains include the control of the firing temperature, the firing time, the pulverization condition, or the like mentioned above; and the application of filtration, classification, or the like.

As the average particle diameter of the abrasive grains, D50% particle diameter of the abrasive grains can be used. The “D50% particle diameter of the abrasive grains” means the median value of volume distribution obtained by measuring a polishing liquid sample in which the abrasive grains are dispersed by a scattering particle size distribution analyzer. The average particle diameter of the abrasive grains can be measured, for example, using LA-920 (trade name) manufactured by HORIBA, Ltd., or the like by the method described in Examples below.

The content of the abrasive grains is preferably in the following range with respect to 100 parts by mass of the CMP polishing liquid. The content of the abrasive grains is preferably 0.01 parts by mass or more, more preferably 0.05 parts by mass or more, further preferably 0.08 parts by mass or more, particularly preferably 0.1 parts by mass or more, extremely preferably 0.15 parts by mass or more, highly preferably 0.2 parts by mass or more, even more preferably 0.3 parts by mass or more, further preferably 0.5 parts by mass or more, particularly preferably 0.8 parts by mass or more, and extremely preferably 1.0 part by mass or more, from the viewpoint of easily achieving a high polishing rate. The content of the abrasive grains is preferably 10 parts by mass or less, more preferably 5.0 parts by mass or less, further preferably 3.0 parts by mass or less, particularly preferably 2.0 parts by mass or less, extremely preferably less than 2.0 parts by mass, highly preferably 1.5 parts by mass or less, and even more preferably 1.0 part by mass or less, from the viewpoint of easily suppressing the aggregation of the abrasive grains and the viewpoint of easily achieving a high polishing rate. From these viewpoints, the content of the abrasive grains is preferably 0.01 to 10 parts by mass and more preferably 0.1 to 10 parts by mass.

### Cationic Polymer

The CMP polishing liquid of the present embodiment contains a cationic polymer having a main chain containing a nitrogen atom and a carbon atom and a hydroxyl group bonded to the carbon atom (hereinafter, referred to as “specific cationic polymer”). The hydroxyl group is bonded directly to the carbon atom of the main chain. The specific cationic polymer can be used as a flattening agent. The “main chain” refers to the longest molecular chain. The “specific cationic polymer” is defined as a polymer having a cation group or a group which can be ionized to a cation group. Examples of the cation group include an amino group and an imino group. The specific cationic polymer can be used singly or in combination of two or more types thereof.

The specific cationic polymer preferably includes a structure unit having a main chain containing a nitrogen atom and a carbon atom, from the viewpoint of easily obtaining the non-linear load dependency of the polishing rate and the viewpoint of easily achieving both of high step height removability and a high polishing rate ratio. The specific cationic polymer also preferably includes a plurality of kinds (for example, two kinds) of structure units having a main chain containing a nitrogen atom and a carbon atom, from the viewpoint of easily obtaining the non-linear load dependency of the polishing rate and the viewpoint of easily achieving both of high step height removability and a high polishing rate ratio.

The specific cationic polymer preferably satisfies at least one of the following properties and more preferably includes a structure unit satisfying at least one of the following properties (a structure unit having a main chain containing a nitrogen atom and a carbon atom), from the viewpoint of easily obtaining the non-linear load dependency of the polishing rate and the viewpoint of easily achieving both of high step height removability and a high polishing rate ratio.

The main chain containing a nitrogen atom and a carbon atom preferably contains a nitrogen atom and an alkylene chain bonded to the nitrogen atom. The hydroxyl group is preferably bonded to the carbon atom of the alkylene chain. The number of carbon atoms of the alkylene chain is 1 or more, preferably 2 or more, and more preferably 3 or more. The number of carbon atoms of the alkylene chain is preferably 6 or less, more preferably 5 or less, and further preferably 4 or less. The number of carbon atoms of the alkylene chain is preferably 1 to 6.

The specific cationic polymer preferably contains a nitrogen atom constituting a quaternary ammonium salt. The quaternary ammonium salt preferably contains a nitrogen atom to which at least one selected from the group consisting of an alkyl group and an aryl group is bonded and more preferably contains a nitrogen atom to which a methyl group is bonded. The quaternary ammonium salt preferably contains a nitrogen atom to which two alkyl groups are bonded and more preferably contains a nitrogen atom to which two methyl groups are bonded. The quaternary ammonium salt preferably contains an ammonium cation and a chloride ion.

The specific cationic polymer preferably contains a nitrogen atom constituting an acid addition salt and more preferably contains a nitrogen atom constituting a hydrochloride salt.

The nitrogen atom may or may not be adjacent to the carbon atom to which the hydroxyl group is bonded. The specific cationic polymer preferably has a hydrocarbon group intervening between the nitrogen atom and the carbon atom to which the hydroxyl group is bonded and more preferably has a hydrocarbon group with one carbon atom (for example, a methylene group) intervening between the nitrogen atom and the carbon atom to which the hydroxyl group is bonded, from the viewpoint of easily obtaining the non-linear load dependency of the polishing rate and the viewpoint of easily achieving both of high step height removability and a high polishing rate ratio. The specific cationic polymer preferably includes a structure unit having a hydrocarbon group intervening between the nitrogen atom and the carbon atom to which the hydroxyl group is bonded and more preferably includes a structure unit having a hydrocarbon group with one carbon atom (for example, a methylene group) intervening between the nitrogen atom and the carbon atom to which the hydroxyl group is bonded, as the structure unit having a main chain containing a nitrogen atom and a carbon atom, from the viewpoint of easily obtaining the non-linear load dependency of the polishing rate and the viewpoint of easily achieving both of high step height removability and a high polishing rate ratio.

The specific cationic polymer preferably contains a reaction product (for example, a condensate) of a raw material containing at least dimethylamine and epichlorohydrin, from the viewpoint of easily obtaining the non-linear load dependency of the polishing rate and the viewpoint of easily achieving both of high step height removability and a high polishing rate ratio. The specific cationic polymer also preferably contains a reaction product (for example, a condensate) of a raw material containing at least dimethylamine, ammonia, and epichlorohydrin, from the viewpoint of easily obtaining the non-linear load dependency of the polishing rate and the viewpoint of easily achieving both of high step height removability and a high polishing rate ratio. The raw material providing a reaction product may contain a compound other than dimethylamine, ammonia, and epichlorohydrin. The specific cationic polymer preferably contains a compound having a structure represented by the following formula, from the viewpoint of easily obtaining the non-linear load dependency of the polishing rate and the viewpoint of easily achieving both of high step height removability and a high polishing rate ratio. The specific cationic polymer preferably contains at least one selected from the group consisting of dimethylamine/epichlorohydrin condensate (polycondensate) and dimethylamine/ammonia/epichlorohydrin condensate (polycondensate), from the viewpoint of easily obtaining the non-linear load dependency of the polishing rate and the viewpoint of easily achieving both of high step height removability and a high polishing rate ratio. The CMP polishing liquid of the present embodiment may not contain a reaction product (for example, a condensate) of a raw material containing dimethylamine, epichlorohydrin, and ethylenediamine as the specific cationic polymer.

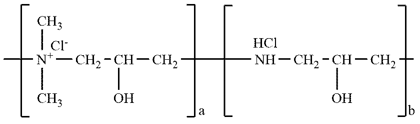

[In the formula, “a” represents an integer of 1 or more, and “b” represents an integer of 0 or more (for example, 1 or more).]

The molecular weight (for example, weight average molecular weight) of the specific cationic polymer is preferably in the following range from the viewpoint that the specific cationic polymer is easily reacted with a material to be polished (for example, an insulating material such as silicon oxide) to be strongly adsorbed to the material to be polished, and thereby the non-linear load dependency of the polishing rate is easily obtained and both of high step height removability and a high polishing rate ratio are easily achieved. The molecular weight of the specific cationic polymer is preferably 10000 or more, more preferably 30000 or more, further preferably 50000 or more, particularly preferably 80000 or more, extremely preferably 100000 or more, highly preferably 200000 or more, even more preferably 300000 or more, further preferably 400000 or more, and particularly preferably 450000 or more. The molecular weight of the specific cationic polymer may be 500000 or more, 600000 or more, 800000 or more, 1000000 or more, or 1200000 or more. The molecular weight of the specific cationic polymer is preferably 2000000 or less, more preferably 1500000 or less, further preferably 1300000 or less, particularly preferably 1200000 or less, extremely preferably 1000000 or less, highly preferably 800000 or less, even more preferably 600000 or less, and further preferably 500000 or less. From these viewpoints, the molecular weight of the specific cationic polymer is preferably 10000 to 2000000, more preferably 10000 to 1000000, further preferably 50000 to 500000, and particularly preferably 100000 to 500000. The molecular weight (for example, weight average molecular weight) of the specific cationic polymer can be measured by the method described in Examples.

The specific cationic polymer is preferably water soluble. By using a compound having a high degree of solubility in water, a desired amount of the specific cationic polymer can be satisfactorily dissolved in the CMP polishing liquid. The degree of solubility of the specific cationic polymer with respect to 100 g of water at room temperature (25° C.) is preferably 0.005 g or more and more preferably 0.02 g or more. The upper limit of the degree of solubility is not particularly limited.

The content of the specific cationic polymer is preferably in the following range with respect to 100 parts by mass of the CMP polishing liquid. The content of the specific cationic polymer is preferably 0.00001 parts by mass or more, more preferably 0.00005 parts by mass or more, further preferably 0.0001 parts by mass or more, particularly preferably 0.0005 parts by mass or more, extremely preferably 0.0008 parts by mass or more, highly preferably 0.001 parts by mass or more, even more preferably more than 0.001 parts by mass, further preferably 0.0011 parts by mass or more, particularly preferably 0.00112 parts by mass or more, and extremely preferably 0.00113 parts by mass or more, from the viewpoint of easily and efficiently obtaining the effect of step height removability and the viewpoint of easily improving flatness. The content of the specific cationic polymer is preferably 10 parts by mass or less, more preferably 5 parts by mass or less, further preferably 2.5 parts by mass or less, particularly preferably less than 2.5 parts by mass, extremely preferably 2 parts by mass or less, highly preferably 1 part by mass or less, even more preferably 0.5 parts by mass or less, further preferably 0.1 parts by mass or less, particularly preferably 0.05 parts by mass or less, extremely preferably 0.01 parts by mass or less, highly preferably less than 0.01 parts by mass, even more preferably 0.005 parts by mass or less, further preferably 0.004 parts by mass or less, particularly preferably 0.003 parts by mass or less, extremely preferably 0.002 parts by mass or less, highly preferably 0.0015 parts by mass or less, even more preferably 0.0013 parts by mass or less, further preferably 0.0012 parts by mass or less, particularly preferably 0.00115 parts by mass or less, and extremely preferably 0.00113 parts by mass or less, from the viewpoint of easily suppressing the aggregation of the abrasive grains and easily obtaining the effect of achieving high step height removability in a stable and efficient manner and the viewpoint of easily preventing deterioration of the CMP polishing liquid and easily storing the CMP polishing liquid in a stable state. The content of the specific cationic polymer is preferably 0.00112 parts by mass or less, more preferably 0.0011 parts by mass or less, or further preferably 0.001 parts by mass or less, from the viewpoint of easily achieving a high polishing rate. From these viewpoints, the content of the specific cationic polymer is preferably 0.00001 to 10 parts by mass, more preferably 0.00001 to 5 parts by mass, further preferably 0.00001 to 1 part by mass, particularly preferably 0.00005 to 0.5 parts by mass, and extremely preferably 0.0001 to 0.1 parts by mass. The content of the specific cationic polymer can be appropriately adjusted according to the type of the specific cationic polymer.

The content of the specific cationic polymer in the CMP polishing liquid of the aforementioned Embodiment A is preferably in the following range with respect to 100 parts by mass of the CMP polishing liquid. The content of the specific cationic polymer is preferably 0.00001 parts by mass or more, more preferably 0.00005 parts by mass or more, further preferably 0.0001 parts by mass or more, particularly preferably 0.0005 parts by mass or more, extremely preferably 0.0008 parts by mass or more, highly preferably 0.001 parts by mass or more, even more preferably more than 0.001 parts by mass, further preferably 0.0011 parts by mass or more, particularly preferably 0.00113 parts by mass or more, extremely preferably 0.0015 parts by mass or more, highly preferably 0.002 parts by mass or more, even more preferably 0.003 parts by mass or more, and further preferably 0.004 parts by mass or more, from the viewpoint of easily achieving both of high step height removability and a high polishing rate ratio. The content of the specific cationic polymer is preferably 10 parts by mass or less, more preferably 5 parts by mass or less, further preferably 2.5 parts by mass or less, particularly preferably less than 2.5 parts by mass, extremely preferably 2 parts by mass or less, highly preferably 1 part by mass or less, even more preferably 0.5 parts by mass or less, further preferably 0.1 parts by mass or less, particularly preferably 0.05 parts by mass or less, extremely preferably 0.01 parts by mass or less, highly preferably less than 0.01 parts by mass, even more preferably 0.005 parts by mass or less, and even more preferably 0.004 parts by mass or less, from the viewpoint of easily suppressing excessive adsorption of the specific cationic polymer to a material to be polished and easily achieving both of high step height removability and a high polishing rate ratio in a stable and efficient manner. The content of the specific cationic polymer may be 0.003 parts by mass or less or 0.002 parts by mass or less. From these viewpoints, the content of the specific cationic polymer is preferably 0.00001 to 10 parts by mass, more preferably 0.00001 to 5 parts by mass, further preferably 0.00001 to 1 part by mass, particularly preferably 0.00005 to 0.5 parts by mass, and extremely preferably 0.0001 to 0.1 parts by mass.

### Cyclic Compound

As the CMP polishing liquid of the aforementioned Embodiment A, the CMP polishing liquid of the present embodiment can contain at least one cyclic compound (excluding a compound corresponding to the specific cationic polymer; hereinafter, referred to as “specific cyclic compound”) selected from the group consisting of an amino group-containing aromatic compound (an amino group-containing aromatic ring compound; excluding a compound corresponding to a nitrogen-containing heterocyclic compound) and a nitrogen-containing heterocyclic compound. The specific cyclic compound can be used singly or in combination of two or more types thereof.

The amino group-containing aromatic compound is a compound having an amino group and an aromatic ring (excluding a nitrogen-containing heteroaromatic ring). The amino group-containing aromatic compound may have an amino group bonded to an aromatic ring.

Examples of the aromatic ring include a benzene ring, a naphthalene ring, and an anthracene ring. The amino group-containing aromatic compound preferably contains a compound having a benzene ring from the viewpoint of easily achieving both of high step height removability and a high polishing rate ratio.

The amino group-containing aromatic compound may have a functional group (excluding an amino group) bonded to an aromatic ring. Examples of such a functional group include a carboxy group, a carboxylate group, a hydroxy group, an alkoxy group, an alkyl group, an ester group, a sulfo group, a sulfonate group, a carbonyl group, an amide group, a carboxamide group, a nitro group, a cyano group, and a halogen atom. The number of functional groups bonded to an aromatic ring is preferably 1, 2, or 3 from the viewpoint of easily achieving both of high step height removability and a high polishing rate ratio. The amino group-containing aromatic compound preferably contains a compound having at least one selected from the group consisting of a carboxy group and a carboxylate group as a functional group bonded to an aromatic ring, from the viewpoint of easily achieving both of high step height removability and a high polishing rate ratio.

Examples of the amino group-containing aromatic compound include aminobenzene (aniline), aminobenzoic acid (such as 2-aminobenzoic acid, 3-pyridinecarboxylic acid, or 4-pyridinecarboxylic acid), aminobenzoate (for example, sodium aminobenzoate), aminophenol, aminoalkoxybenzene, alkylaminobenzene, aminobenzoic acid ester, and aminobenzenesulfonic acid. The amino group-containing aromatic compound preferably contains a compound having an amino group and at least one selected from the group consisting of a carboxy group and a carboxylate group as a functional group bonded to an aromatic ring and more preferably contains at least one selected from the group consisting of aminobenzoic acid and aminobenzoate, from the viewpoint of easily achieving both of high step height removability and a high polishing rate ratio.

The nitrogen-containing heterocyclic compound is a compound having a nitrogen-containing heterocyclic ring. Examples of the nitrogen-containing heterocyclic ring include a pyridine ring, an imidazole ring (also including a benzimidazole ring), a pyrrole ring, a pyrimidine ring, a morpholine ring, a pyrrolidine ring, a piperidine ring, a piperazine ring, a pyrazine ring, and a lactam ring (such as a pyrrolidone ring, a piperidone ring, or ε-caprolactam ring). The nitrogen-containing heterocyclic ring may be a 5-membered ring or a 6-membered ring. The number of nitrogen atoms in the nitrogen-containing heterocyclic ring may be 1 or 2. The nitrogen-containing heterocyclic compound preferably contains a compound having a nitrogen-containing heteroaromatic ring and more preferably contains a compound having a pyridine ring (a pyridine compound), from the viewpoint of easily achieving both of high step height removability and a high polishing rate ratio.

The nitrogen-containing heterocyclic compound may have a functional group bonded to a nitrogen-containing heterocyclic ring. Examples of such a functional group include a carboxy group, a carboxylate group, a hydroxy group, an alkoxy group, an alkyl group, an ester group, a sulfo group, a sulfonate group, a carbonyl group, an amino group, an amide group, a carboxamide group, a nitro group, a cyano group, and a halogen atom. The number of functional groups bonded to a nitrogen-containing heterocyclic ring is preferably 1, 2, or 3 from the viewpoint of easily achieving both of high step height removability and a high polishing rate ratio. The nitrogen-containing heterocyclic compound preferably contains a compound having at least one selected from the group consisting of a carboxy group, a carboxylate group, a carbonyl group, and a carboxamide group as a functional group bonded to a nitrogen-containing heterocyclic ring, from the viewpoint of easily achieving both of high step height removability and a high polishing rate ratio.

Examples of the nitrogen-containing heterocyclic compound include pyridine, pyridinecarboxylic acid (such as 2-pyridinecarboxylic acid, 3-pyridinecarboxylic acid, or 4-pyridinecarboxylic acid), pyridinyl ketone (such as 1-(2-pyridinyl)-1-ethanone), pyridinyl carboxamide (such as pyridine-3-carboxamide), imidazole, benzimidazole, pyrrole, pyrimidine, morpholine, pyrrolidine, piperidine, piperazine, and pyrazine. The amino group-containing aromatic compound preferably contains at least one selected from the group consisting of a pyridinecarboxylic acid, 1-(2-pyridinyl)-1-ethanone, and pyridine-3-carboxamide from the viewpoint of easily achieving both of high step height removability and a high polishing rate ratio.

The content of the specific cyclic compound, the content of the amino group-containing aromatic compound, or the content of the nitrogen-containing heterocyclic compound is preferably in the following range with respect to 100 parts by mass of the CMP polishing liquid. The content of each compound mentioned above is preferably 0.001 parts by mass or more, more preferably 0.002 parts by mass or more, further preferably 0.005 parts by mass or more, particularly preferably 0.01 parts by mass or more, extremely preferably 0.03 parts by mass or more, highly preferably 0.05 parts by mass or more, even more preferably 0.08 parts by mass or more, further preferably 0.1 parts by mass or more, particularly preferably 0.12 parts by mass or more, extremely preferably 0.15 parts by mass or more, and highly preferably 0.2 parts by mass or more, from the viewpoint of easily achieving both of high step height removability and a high polishing rate ratio in a stable manner. The content of each compound mentioned above is preferably 1 part by mass or less, more preferably 0.8 parts by mass or less, further preferably 0.5 parts by mass or less, particularly preferably 0.3 parts by mass or less, and extremely preferably 0.2 parts by mass or less, from the viewpoint of easily dissolving the specific cyclic compound sufficiently and easily achieving both of high step height removability and a high polishing rate ratio. From these viewpoints, the content of each compound mentioned above is preferably 0.001 to 1 part by mass and more preferably 0.002 to 1 part by mass.

The CMP polishing liquid of the present embodiment may not contain the specific cyclic compound as the CMP polishing liquid of an embodiment different from the aforementioned Embodiment A. The content of the specific cyclic compound, the content of the amino group-containing aromatic compound, or the content of the nitrogen-containing heterocyclic compound may be 0.0001 parts by mass or less, less than 0.0001 parts by mass, 0.00005 parts by mass or less, 0.00001 parts by mass or less, less than 0.00001 parts by mass, or substantially 0 parts by mass, with respect to 100 parts by mass of the CMP polishing liquid.

### Water

The CMP polishing liquid of the present embodiment can contain water. Water is not particularly limited, and is preferably at least one selected from the group consisting of deionized water, ion-exchange water, and ultrapure water.

### Polishing Rate Improver

The CMP polishing liquid of the present embodiment can contain a polishing rate improver and may not contain a polishing rate improver. Examples of the polishing rate improver include salicylaldoxime. Salicylaldoxime can be used as a polishing rate improver that improves a polishing rate for a material to be polished (for example, an insulating material such as silicon oxide).

The content of the polishing rate improver (for example, salicylaldoxime) is preferably in the following range with respect to 100 parts by mass of the CMP polishing liquid. The content of the polishing rate improver is preferably 0.001 parts by mass or more, more preferably 0.003 parts by mass or more, further preferably 0.005 parts by mass or more, particularly preferably 0.01 partsby mass or more, extremely preferably 0.02 parts by mass or more, and highly preferably 0.03 parts by mass or more, from the viewpoint of easily achieving a high polishing rate. The content of the polishing rate improver is preferably 10 parts by mass or less, more preferably 5 parts by mass or less, further preferably 1 part by mass or less, particularly preferably 0.5 parts by mass or less, extremely preferably 0.1 parts by mass or less, highly preferably 0.08 parts by mass or less, even more preferably 0.05 parts by mass or less, further preferably 0.04 parts by mass or less, and particularly preferably 0.035 parts by mass or less, from the viewpoint of easily achieving a high polishing rate. From these viewpoints, the content of the polishing rate improver is preferably 0.001 to 10 parts by mass and more preferably 0.01 to 10 parts by mass. The polishing rate improver may contain salicylaldoxime, and the content of salicylaldoxime is preferably in each range of the aforementioned content of the polishing rate improver with respect to 100 parts by mass of the CMP polishing liquid.

### Surfactant

The CMP polishing liquid of the present embodiment can contain a surfactant from the viewpoint of further improving the dispersion stability of the abrasive grains and/or the flatness of a polished surface. Examples of the surfactant include an ionic surfactant and a nonionic surfactant, and a nonionic surfactant is preferred from the viewpoint of easily improving the dispersion stability of the abrasive grains in the CMP polishing liquid. The surfactant can be used singly or in combination of two or more types thereof.

Examples of the nonionic surfactant include ether-type surfactants such as polyoxypropylene polyoxyethylene alkyl ether, polyoxyethylene alkyl ether, polyoxyethylene alkylaryl ether, polyoxyethylene polyoxypropylene ether derivatives, polyoxypropylene glyceryl ether, oxyethylene adducts of polyethylene glycol, oxyethylene adducts of methoxypolyethylene glycol, oxyethylene adducts of acethylene-based diols; ester-type surfactants such as sorbitan fatty acid ester and glycerol borate fatty acid ester; amino ether-type surfactants such as polyoxyethylene alkylamine; ether ester-type surfactants such as polyoxyethylene sorbitan fatty acid ester, polyoxyethylene glycerol borate fatty acid ester, and polyoxyethylene alkyl ester; alkanolamide-type surfactants such as fatty acid alkanolamide and polyoxyethylene fatty acid alkanolamide; oxyethylene adducts of acetylene-based diols; polyvinylpyrrolidone; polyacrylamide; polydimethylacrylamide; and polyvinyl alcohol. The nonionic surfactant can be used singly or in combination of two or more types thereof.

### Other Components

The CMP polishing liquid of the present embodiment may contain other component to meet a desired property. Examples of such component include a pH adjusting agent described below; a pH buffering agent for suppressing a variation in pH; an organic solvent such as ethanol or acetone; a 4-pyrone-based compound; aminocarboxylic acid; and cyclic monocarboxylic acid.

The content of guanidine carbonate may be 0.001% by mass or less, less than 0.001% by mass, or 0.0001% by mass or less, with respect to 100 parts by mass of the CMP polishing liquid. The CMP polishing liquid of the present embodiment may not contain guanidine carbonate (the content of guanidine carbonate may be substantially 0 parts by mass with respect to 100 parts by mass of the CMP polishing liquid). The content of hydroxyalkyl cellulose may be 0.005% by mass or less, less than 0.005% by mass, or 0.001% by mass or less, with respect to 100 parts by mass of the CMP polishing liquid. The CMP polishing liquid of the present embodiment may not contain hydroxyalkyl cellulose (the content of hydroxyalkyl cellulose may be substantially 0 parts by mass with respect to 100 parts by mass of the CMP polishing liquid).

### pH

The pH of the CMP polishing liquid of the present embodiment is preferably in the following range. The pH is preferably 8.0 or less, more preferably less than 8.0, further preferably 7.0 or less, particularly preferably 6.0 or less, extremely preferably less than 6.0, highly preferably 5.0 or less, even more preferably 4.5 or less, further preferably 4.0 or less, and particularly preferably 3.5 or less, from the viewpoint of improving the wettability between the CMP polishing liquid and a material to be polished (for example, an insulating material such as silicon oxide), the viewpoint of easily suppressing the aggregation of the abrasive grains, and the viewpoint of easily obtaining the effect obtained by addition of the specific cationic polymer. The pH is preferably 1.5 or more, more preferably 2.0 or more, further preferably 2.5 or more, particularly preferably 3.0 or more, extremely preferably more than 3.0, highly preferably 3.2 or more, and even more preferably 3.5 or more, from the viewpoint that a larger absolute value for the zeta potential of a material to be polished (for example, an insulating material such as silicon oxide) will be obtainable, and a higher polishing rate is easily achieved. From these viewpoints, the pH is preferably 1.5 to 8.0 and more preferably 2.0 to 5.0. The pH is defined as the pH at a liquid temperature of 25° C.

The pH of the CMP polishing liquid of the aforementioned Embodiment A is preferably in the following range. The pH is preferably 8.0 or less, more preferably less than 8.0, further preferably 7.0 or less, particularly preferably 6.0 or less, extremely preferably less than 6.0, highly preferably 5.0 or less, even more preferably 4.5 or less, further preferably 4.0 or less, and particularly preferably 3.5 or less, from the viewpoint of improving the wettability between the CMP polishing liquid and a material to be polished (for example, an insulating material such as silicon oxide), the viewpoint of easily suppressing the aggregation of the abrasive grains, and the viewpoint of easily obtaining the effect obtained by addition of the specific cationic polymer. The pH is preferably 1.5 or more, preferably 2.0 or more, more preferably 2.5 or more, further preferably 3.0 or more, particularly preferably more than 3.0, extremely preferably 3.2 or more, and highly preferably 3.5 or more, from the viewpoint that a smaller absolute value for the zeta potential of a material to be polished (for example, an insulating material such as silicon oxide) will be obtainable, and a higher polishing rate is easily achieved. From these viewpoints, the pH is preferably 2.0 to 8.0 and more preferably 2.0 to 5.0.

The pH of the CMP polishing liquid of the present embodiment can be measured by a pH meter (for example, Model No. D-71S manufactured by HORIBA, Ltd.). For example, after performing 3-point calibration of the pH meter using a phthalate pH buffer solution (pH: 4.01), a neutral phosphate pH buffer solution (pH: 6.86), and a borate pH buffer solution (pH: 9.18) as standard buffer solutions, an electrode of the pH meter is placed in the CMP polishing liquid, and the pH upon stabilization after an elapse of 3 minutes or longer is measured. At this time, both the liquid temperatures of the standard buffer solutions and the CMP polishing liquid are set to 25° C.

It is conceivable that the following two effects are obtained by adjusting the pH of the CMP polishing liquid within a range of 1.5 to 8.0 (for example, 2.0 to 8.0).
(1) Protons or hydroxy anions act on the compound blended as an additive, the chemical form of this compound is changed, and the wettability and affinity with respect to silicon oxide and/or the stopper material (for example, silicon nitride) of the base substrate surface are improved.
(2) In a case where the abrasive grains contain cerium oxide, the contact efficiency between the abrasive grains and the silicon oxide film is improved, and a higher polishing rate is achieved. The reason for this is conceivable that the sign for the zeta potential of cerium oxide is positive while the sign for the zeta potential of the silicon oxide film is 0 or negative, such that electrostatic attraction works between them.

The pH of the CMP polishing liquid may change depending on the type of a compound used as an additive. Therefore, the CMP polishing liquid may contain a pH adjusting agent for adjusting the pH to the above range. Examples of the pH adjusting agent include an acid component and a base component. Examples of the acid component include organic acids such as propionic acid and acetic acid (excluding compounds corresponding to amino acids); inorganic acids such as nitric acid, sulfuric acid, hydrochloric acid, phosphoric acid, and boric acid; and amino acids such as glycine. Examples of the base component include sodium hydroxide, ammonia, potassium hydroxide, and calcium hydroxide. The CMP polishing liquid of the present embodiment may contain an acid component and may contain an organic acid. From the viewpoint of improving productivity, a CMP polishing liquid prepared without using a pH adjusting agent may be used directly for CMP.

### Polishing Method

A polishing method of the present embodiment includes a polishing step of polishing a material to be polished by using the CMP polishing liquid of the present embodiment. The polishing step is, for example, a step of polishing an insulating material (for example, an insulating material such as silicon oxide) of a base substrate having the insulating material on the surface thereof by using the CMP polishing liquid of the present embodiment. The polishing step is, for example, a step of polishing a material to be polished by a polishing member while supplying the CMP polishing liquid of the present embodiment between a material to be polished (for example, an insulating material) and the polishing member (such as a polishing pad). The material to be polished may contain an insulating material, may contain an inorganic insulating material, and may contain silicon oxide. The polishing step is, for example, a step of flattening a base substrate having an insulating material (for example, an insulating material such as silicon oxide) on the surface thereof by the CMP technique using a CMP polishing liquid in which the content of each component, the pH, and the like are adjusted. The material to be polished may be in the form of a film (film to be polished) and may be an insulating film such as a silicon oxide film.

The polishing method of the present embodiment is suitable for polishing the base substrate having a material to be polished (for example, an insulating material such as silicon oxide) on the surface thereof in the production process of a device as described below. Examples of the device include a discrete semiconductor such as diode, transistor, compound semiconductor, thermistor, varistor, and thyristor; a memory element such as DRAM (dynamic random access memory), SRAM (static random access memory), EPROM (erasable programmable read-only memory), mask ROM (mask read-only memory), EEPROM (electrically erasable programmable read-only memory), and flash memory; a logic circuit element such as a microprocessor, DSP, and ASIC; an integrated circuit element such as a compound semiconductor typified by MMIC (monolithic microwave integrated circuit); a hybrid integrated circuit (hybrid IC) and a photoelectric conversion element such as light emitting diode and charge-coupled element.

The polishing method of the present embodiment is particularly suitable for flattening of a surface of a base substrate having step height (irregularities) on the surface thereof. In the present embodiment, since both of high step height removability and high flatness can be achieved, it is possible to polish various base substrates that have been difficult to polish by methods using conventional CMP polishing liquids. Examples of the base substrate include logic semiconductor devices and memory semiconductor devices. The material to be polished may be a material to be polished (for example, an insulating material such as silicon oxide) having a step height of 1 µm or more or a material to be polished having a portion with a concave portion or a convex portion in a T-shaped or lattice-shaped fashion when viewed from above. For example, an object to be polished having a material to be polished may be a semiconductor substrate having a memory cell. According to the present embodiment, an insulating material (for example, an insulating material such as silicon oxide) provided on a surface of a semiconductor device (a DRAM, a flash memory, or the like) including a semiconductor substrate having a memory cell can also be polished at a high polishing rate. According to the present embodiment, an insulating material (for example, an insulating material such as silicon oxide) provided on a surface of a 3D-NAND flash memory can also be polished at a high polishing rate while securing high flatness.

The object to be polished is not limited to a base substrate having silicon oxide covering the entire surface, and may be a base substrate further having silicon nitride, polycrystalline silicon, or the like other than the silicon oxide on the surface thereof. The object to be polished may be a base substrate in which an insulating material (for example, an inorganic insulating material such as silicon oxide, glass, or silicon nitride), polysilicon, Al, Cu, Ti, TiN, W, Ta, TaN, or the like is formed on a wiring board having a predetermined wiring.

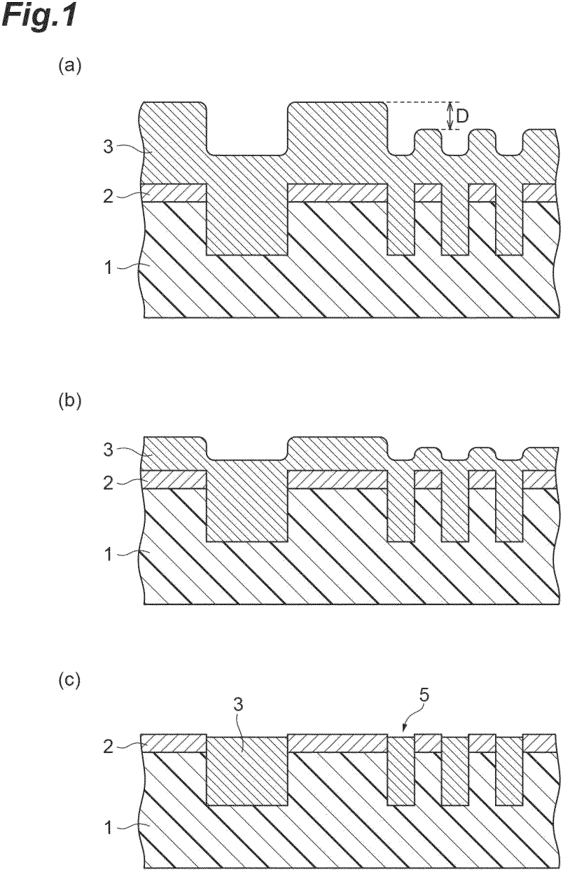

A process in which an STI structure is formed on a base substrate (wafer) by CMP in the polishing method of the present embodiment will be described with reference to FIG. 1. FIG. 1 is a schematic cross-sectional view illustrating a process in which a silicon oxide film is polished to form an STI structure. The polishing method of the present embodiment includes a first step (rough polishing step) in which a silicon oxide film 3 is polished with high step height removability (a high polishing rate) and a second step (finishing step) in which the remaining portion of the silicon oxide film 3 is polished at a relatively low polishing rate so as to have an arbitrary film thickness.

FIG. 1(a) is a cross-sectional view illustrating a base substrate before polishing. FIG. 1(b) is a cross-sectional view illustrating the base substrate after the first step. FIG. 1(c) is a cross-sectional view illustrating the base substrate after the second step. As illustrated in these drawings, during the process of forming an STI structure, the partially protruding unnecessary sections are preferentially removed by CMP in order to eliminate a step height D of the silicon oxide film 3 formed on a silicon substrate 1. In order to stop polishing at an appropriate point when the surface has been flattened, a silicon nitride film (stopper film) 2 with a slow polishing rate is preferably formed in advance under the silicon oxide film 3. The step height (difference of elevation of film thickness) D of the silicon oxide film 3 is eliminated through the first step and the second step, and an element isolation structure having an embedded portion 5 is formed.

For polishing of the silicon oxide film 3, the base substrate is disposed on the polishing pad such that the surface of the silicon oxide film 3 contacts the polishing pad, and the surface of the silicon oxide film 3 is polished by the polishing pad. More specifically, the silicon oxide film 3 is polished by pressing the surface to be polished of the silicon oxide film 3 against the polishing pad of a polishing platen and relatively moving the surface to be polished and the polishing pad while supplying the CMP polishing liquid between them.

Since the CMP polishing liquid of the present embodiment has high step height removability and high flatness, the CMP polishing liquid can be applied to both the first step and the second step and can be suitably used in the second step. Herein, a case where the polishing step is divided into two stages and carried out has been illustrated, but from the viewpoint of productivity and facility simplification, the polishing treatment can also be performed in a single stage from the state illustrated in FIG. 1(a) to the state illustrated in FIG. 1(c).

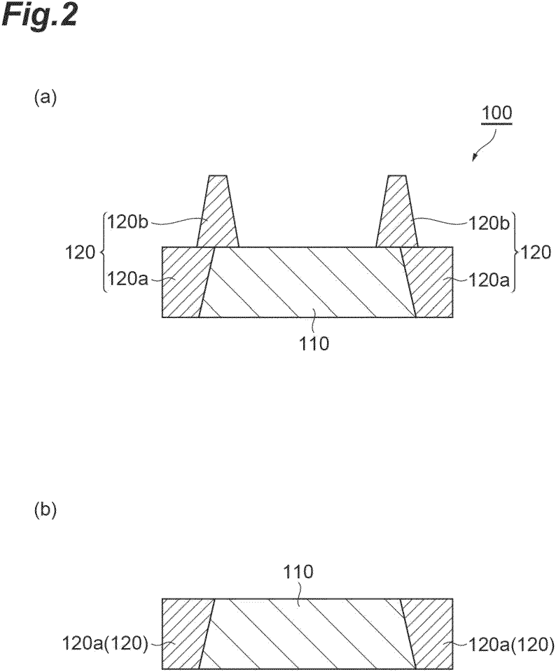

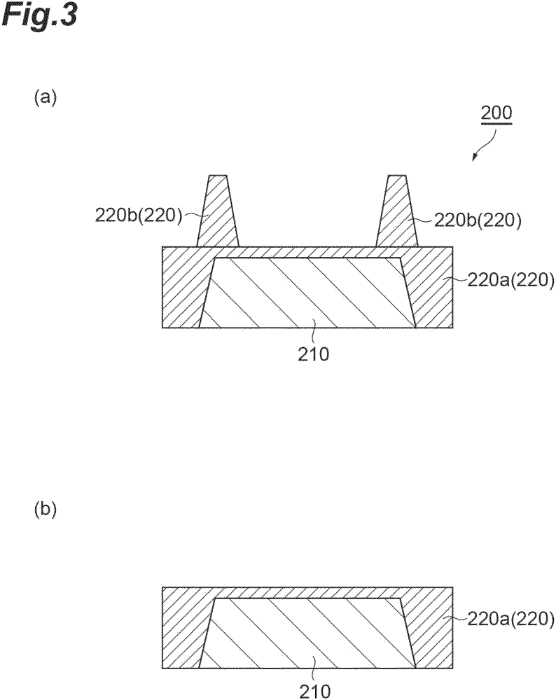

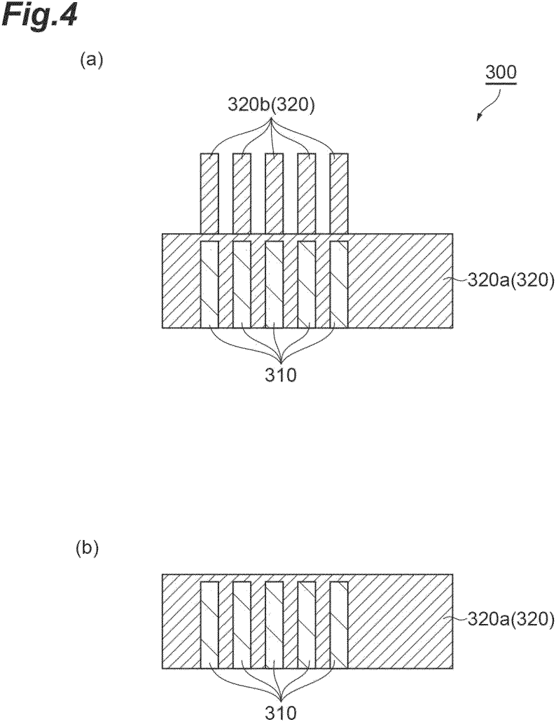

FIGS. 2 to 4 are schematic cross-sectional views each illustrating a process in which a base substrate is polished in the polishing method of the present embodiment, and are schematic cross-sectional views each illustrating a process in which a material to be polished having irregularities is polished to eliminate the irregularities. (a) of FIGS. 2 to 4 is a cross-sectional view illustrating a base substrate before polishing. (b) of FIGS. 2 to 4 is a cross-sectional view illustrating a base substrate after polishing.

Base substrates 100, 200, and 300 illustrated in (a) of FIGS. 2 to 4 include integrated memory cells 110, 210, and 310; and insulating members (for example, silicon oxide members) 120, 220, and 320 disposed around the integrated memory cells 110, 210, and 310 and also disposed on integrated memory cells 110, 210, and 310, respectively. The base substrates 100 and 200 have one integrated memory cell 110 and one integrated memory cell 210 respectively, and the base substrate 300 has a plurality of integrated memory cells 310 disposed with the insulating member 320 interposed therebetween. The insulating member 120 in the base substrate 100 has a lower layer part 120a disposed around the integrated memory cell 110; and an upper layer part 120b disposed on the outer periphery part of the integrated memory cell 110 and also extending in the thickness direction of the integrated memory cell 110. The insulating member 220 in the base substrate 200 has a lower layer part 220a composed of a portion disposed around the integrated memory cell 110 and a portion covering the entire integrated memory cell 210 on the integrated memory cell 210; and an upper layer part 220b positioned on the upper part of the outer periphery part of the integrated memory cell 110 and also extending in the thickness direction of the integrated memory cell 210. The insulating member 320 in the base substrate 300 has a lower layer part 320a composed of a portion disposed around the integrated memory cell 310, a portion disposed between the integrated memory cells 310, and a portion covering the entire integrated memory cell 310 on the integrated memory cell 310; and an upper layer part 320b positioned on the upper part of each of the integrated memory cells 310 and also extending in the thickness direction of the integrated memory cell 310.

In the polishing method of the present embodiment, the upper layer parts 120b, 220b, and 320b of the base substrates 100, 200, and 300 are polished and removed, thereby flattening the integrated memory cells 110, 210, and 310. In order to stop polishing at an appropriate point when flattening has been achieved, a stopper film (a silicon nitride film or the like) with a slow polishing rate may be formed in advance below a step height part.

As the polishing apparatus, for example, an apparatus provided with a holder for holding a base substrate, a polishing platen to which a polishing pad is attached, and a means for supplying a CMP polishing liquid onto the polishing pad is suitable. Examples of the polishing apparatus include a polishing apparatus (Model No.: EPO-111, EPO-222, FREX200, FREX300, or the like) manufactured by EBARA CORPORATION and a polishing apparatus (trade name: Mirra3400, Reflexion, or the like) manufactured by Applied Materials, Inc. The polishing pad is not particularly limited, and for example, a general nonwoven fabric, foamed polyurethane, a porous fluororesin, or the like can be used. It is preferable that the polishing pad is subjected to grooving so that the CMP polishing liquid is pooled.

Polishing conditions are not particularly limited, but the rotation speed of the polishing platen is preferably 200 rpm (min⁻¹) or less from the viewpoint that the base substrate is not let out, and the pressure (processing load) to be applied to the base substrate is preferably 100 kPa or less from the viewpoint of easily suppressing scratches on the polished surface. The CMP polishing liquid is preferably continuously supplied to the polishing pad with a pump or the like during polishing. The amount supplied for this is not limited, but it is preferable that the surface of the polishing pad is always covered with the CMP polishing liquid.

It is preferable to sufficiently wash the base material in running water after the completion of polishing, then perform drying after removing droplets, which have attached onto the base substrate, with the use of a spin dry or the like.

Polishing in this manner allows irregularities on the surface to be eliminated, and thereby a smooth surface across the entire base substrate can be obtained. By repeating the formation of a material to be polished and the polishing thereof a predetermined number of times, a base substrate having desired number of layers can be produced.

The base substrate obtained in this way can be used as various electronic components and machine components. Specific examples thereof include semiconductor elements; optical glass for a photomask, a lens, or a prism; inorganic conductive films of ITO or the like; optical integrated circuits/optical switching elements/optical waveguides constituted with glass and crystalline materials; optical single crystals such as end faces of optical fibers and scintillators; solid laser single crystals; sapphire substrates for blue laser LEDs; semiconductor single crystals of SiC, GaP, GaAs, or the like; glass substrates for magnetic discs; and magnetic heads.

A method of producing a component of the present embodiment includes an individually dividing step of dividing a base substrate polished by the polishing method of the present embodiment into individual pieces. The individually dividing step may be, for example, a step of dicing a wafer (for example, a semiconductor wafer) polished by the polishing method of the present embodiment to obtain chips (for example, semiconductor chips). The method of producing a component of the present embodiment may include a step of polishing a base substrate by the polishing method of the present embodiment before the individually dividing step. A component of the present embodiment may be, for example, a chip (for example, a semiconductor chip). The component of the present embodiment is a component obtained by the method of producing a component of the present embodiment. An electronic device of the present embodiment includes the component of the present embodiment.

### EXAMPLES

Hereinafter, the present disclosure will be further specifically described by means of Examples; however, the present disclosure is not limited to these Examples.

### Experiment A

### Preparation of Abrasive Grains

40 kg of cerium carbonate hydrate was placed in an alumina container and fired at 830° C. for 2 hours in air to obtain 20 kg of yellowish-white powder. The phase identification of this powder was performed by an X-ray diffraction method, and it was confirmed that this powder contained polycrystalline cerium oxide. The particle diameter of the powder obtained by firing was observed with a SEM and was found to be 20 to 100 µm. Next, 20 kg of the cerium oxide powder was dry pulverized using a jet mill. The cerium oxide powder after the pulverization was observed with a SEM, and was found to include particles containing polycrystalline cerium oxide having a crystal boundary. Furthermore, the specific surface area of the cerium oxide powder was 9.4 m²/g. The measurement of the specific surface area was performed by the BET method.

### Preparation of CMP Polishing Liquid

15 kg of the aforementioned cerium oxide powder and 84.7 kg of deionized water were placed in a container and mixed. Further, 0.3 kg of 1 N acetic acid aqueous solution was added and stirred for 10 minutes to thereby obtain a cerium oxide mixed liquid. This cerium oxide mixed liquid was send to another container over 30 minutes. Meanwhile, in the sending pipe, the cerium oxide mixed liquid was irradiated with ultrasonic wave at an ultrasonic wave frequency of 400 kHz.

500 g of the cerium oxide mixed liquid was collected in each of four 500 mL beakers and centrifugal separation was performed. The centrifugal separation was carried out for 2 minutes under the conditions that the centrifugal force exerted to the outer circumference was 500 G. The cerium oxide particles (abrasive grains) precipitated at the bottom of the beaker was recovered and the supernatant was taken. The average particle diameter of the abrasive grains in the abrasive grain dispersion liquid with an abrasive grain content of 5% by mass was measured using a dynamic light scattering particle size distribution analyzer (trade name: LA-920 manufactured by HORIBA, Ltd.); as a result, the average particle diameter was 90 nm.

The aforementioned abrasive grains, an additive A described in Table 1, salicylaldoxime, propionic acid, and deionized water were mixed to obtain a CMP polishing liquid containing 1.0% by mass of the abrasive grains, the additive A, 0.034% by mass of salicylaldoxime, 0.09% by mass of propionic acid, and deionized water (remnant). Regarding the content of the additive A, the content thereof in Examples A1, A2, and A4 was adjusted to 0.00100% by mass, the content thereof in Example A3 was adjusted to 0.00113% by mass, the content thereof in Comparative Examples A1 and A3 was adjusted to 0.00800% by mass, and the content thereof in Comparative Example A2 was adjusted to 0.02500% by mass. In the case of supplying the additive A by using the polymer aqueous solution, the above-described content of the additive A was calculated on the basis of the mass of the polymer in the polymer aqueous solution. As the additive A, the following compounds were used.

### Additive A

### Specific Cationic Polymer

A1: Dimethylamine/ammonia/epichlorohydrin polycondensate (manufactured by SENKA corporation, trade name: UNISENCE KHE1001L, weight average molecular weight: 100000 to 500000)

A2: Dimethylamine/ammonia/epichlorohydrin polycondensate (manufactured by SENKA corporation, trade name: UNISENCE KHE105L, weight average molecular weight: 479796 (measured value))

A3: Dimethylamine/ammonia/epichlorohydrin polycondensate (manufactured by SENKA corporation, trade name: UNISENCE KHE1000L, weight average molecular weight: 1296145 (measured value))

### Compound Not Corresponding to Specific Cationic Polymer

A4: Dimethyldiallylammonium chloride polymer (manufactured by SENKA corporation, trade name: UNISENCE FPA1000L)

A5: Vinyl pyrrolidone/N,N-dimethylaminoethylmethacrylic acid copolymer diethyl sulfate salt liquid (manufactured by OSAKA ORGANIC CHEMICAL INDUSTRY LTD., trade name: H.C. Polymer 2L)

A6: Benzenesulfonic acid

The measured values of weight average molecular weights of the aforementioned specific cationic polymers A2 and A3 were converted from the calibration curve using a standard polystyrene by gel permeation chromatography (GPC) under the following conditions. The calibration curve was approximated based on a tertiary expression by using standard polyethylene oxide (manufactured by Tosoh Corporation, SE-2, SE-5, SE-30, and SE-150), pullulan (manufactured by Precision System Science Co., Ltd., pss-dpul 2.5 m), and polyethylene glycol (manufactured by FUJIFILM Wako Pure Chemical Corporation, PEG400, PEG1000, PEG3000, and PEG6000).

Pump: trade name “LC-20AD” manufactured by SHIMADZU CORPORATION

Detector: trade name “RID-10A” manufactured by SHIMADZU CORPORATION

Column oven: trade name “CTO-20AC” manufactured by SHIMADZU CORPORATION

Column: two columns of trade name “TSKGel G6000PW_{XL}-CP” manufactured by Tosoh Corporation were connected in series.
Column size: 7.8 mm I.D × 300 mm
Eluent: 0.1 M sodium nitrate aqueous solution
Sample concentration: 4 mg/2 mL (in terms of N.V.)
Injection amount: 100 µL
Flow rate: 1.0 mL/min
Measurement temperature: 25° C.

The pH of the CMP polishing liquid was measured under the following conditions. The pH in all of Examples and Comparative Examples was 3.5.

Measurement temperature: 25° C.

Measurement apparatus: Model No. D-71S manufactured by HORIBA, Ltd.

Measurement method: After performing 3-point calibration using a standard buffer solution (phthalate pH buffer solution, pH: 4.01 (25° C.); neutral phosphate pH buffer solution, pH: 6.86 (25° C.); borate pH buffer solution, pH: 9.18), an electrode was placed in the CMP polishing liquid, and the pH upon stabilization after an elapse of 3 minutes or longer was measured by the above-described measurement apparatus.

### Polishing Characteristic Evaluation

### Evaluation of Load Dependency of Polishing Rate

A blanket wafer having a silicon oxide film on the surface thereof was polished using each CMP polishing liquid mentioned above under the polishing conditions below to obtain a polishing rate (blanket wafer polishing rate). As the blanket wafer, a wafer that has a silicon oxide film having a film thickness of 1000 nm disposed on a silicon substrate having a diameter of 300 mm was used.

### Polishing Conditions

Polishing apparatus: Polishing machine for CMP, Reflexion-LK (manufactured by Applied Materials, Inc.)

Polishing pad: Porous urethane pad IC-1010 (manufactured by DuPont)

Polishing pressure (load): 3.0 psi or 4.0 psi

Number of revolutions of platen: 126 rpm

Number of revolutions of head: 125 rpm

Amount of CMP polishing liquid to be supplied: 250 mL/min Polishing time: 30 seconds

The load dependency of the polishing rate was evaluated on the basis of a different in polishing rate between a load of 3.0 psi (low load) and a load of 4.0 psi (high load), that is “4.0 psi value - 3.0 psi value”. As shown in Table 1, it is confirmed that in Examples, a large difference in polishing rate between a time when a load of 4.0 psi is applied and a time when a load of 3.0 psi is applied can be achieved and the non-linear load dependency of the polishing rate can be obtained.

Table 1

| | Example | | | | Comparative Example | | |
|---|---|---|---|---|---|---|---|
| | A1 | A2 | A3 | A4 | A1 | A2 | A3 |
| Additive A | A1 | A2 | A3 | A4 | A4 | A5 | A6 |
| Polishing rate [Å/min] @3 psi | 1305 | 1840 | 1028 | 1418 | 1390 | 1800 | 1902 |
| Polishing rate [Å/min] @4 psi | 9006 | 10420 | 9776 | 9321 | 7576 | 7640 | 4300 |
| Difference in polishing rate (4 psi value - 3 psi value) | 7701 | 8580 | 8748 | 7903 | 6186 | 5840 | 2398 |

### Experiment B

### Preparation of Abrasive Grains

40 kg of cerium carbonate hydrate was placed in an alumina container and then fired at 830° C. for 2 hours in air to obtain 20 kg of yellowish-white powder. The phase identification of this powder was performed by an X-ray diffraction method, and it was confirmed that this powder contained polycrystalline cerium oxide. The particle diameter of the powder obtained by firing was observed with a SEM and was found to be 20 to 100 µm. Next, 20 kg of the cerium oxide powder was dry pulverized using a jet mill. The cerium oxide powder after the pulverization was observed with a SEM, and was found to include particles containing polycrystalline cerium oxide having a crystal boundary. Furthermore, the specific surface area of the cerium oxide powder was 9.4 m²/g. The measurement of the specific surface area was performed by the BET method.

### Preparation of CMP Polishing Liquid

15 kg of the aforementioned cerium oxide powder and 84.7 kg of deionized water were placed in a container and mixed. Further, 0.3 kg of 1 N acetic acid aqueous solution was added and stirred for 10 minutes to thereby obtain a cerium oxide mixed liquid. This cerium oxide mixed liquid was send to another container over 30 minutes. Meanwhile, in the sending pipe, the cerium oxide mixed liquid was irradiated with ultrasonic wave at an ultrasonic wave frequency of 400 kHz.

500 g of the cerium oxide mixed liquid was collected in each of four 500 mL beakers and centrifugal separation was performed. The centrifugal separation was carried out for 2 minutes under the conditions that the centrifugal force exerted to the outer circumference was 500 G. The cerium oxide particles (abrasive grains) precipitated at the bottom of the beaker was recovered and the supernatant was taken. The average particle diameter of the abrasive grains in the abrasive grain dispersion liquid with an abrasive grain content of 5% by mass was measured using a dynamic light scattering particle size distribution analyzer (trade name: LA-920 manufactured by HORIBA, Ltd.); as a result, the average particle diameter was 90 nm.

The aforementioned abrasive grains, a cationic polymer (dimethylamine/ammonia/epichlorohydrin polycondensate, manufactured by SENKA corporation, trade name: UNISENCE KHE105L, weight average molecular weight: 479796 (measured value)), a cyclic compound described in Table 2, propionic acid, and deionized water were mixed to obtain a CMP polishing liquid containing 1.0% by mass of the abrasive grains, the cationic polymer, the cyclic compound, 0.09% by mass of propionic acid, and deionized water (balance). The contents of the cationic polymer and the cyclic compound were as shown in Table 2, the cationic polymer was not used in Comparative Examples B2 and B3, and the cyclic compound was not used in Comparative Examples B1 and B2. The content of the cationic polymer was calculated on the basis of the mass of the polymer in the polymer aqueous solution.

The pH of the CMP polishing liquid was measured under the following conditions. The pH in all of Examples and Comparative Examples was 3.5.

Measurement temperature: 25° C.

Measurement apparatus: Model No. D-71S manufactured by HORIBA, Ltd.

Measurement method: After performing 3-point calibration using a standard buffer solution (phthalate pH buffer solution, pH: 4.01 (25° C.); neutral phosphate pH buffer solution, pH: 6.86 (25° C.); borate pH buffer solution, pH: 9.18), an electrode was placed in the CMP polishing liquid, and the pH upon stabilization after an elapse of 3 minutes or longer was measured by the above-described measurement apparatus.

### Polishing Characteristic Evaluation

### Evaluation of Load Dependency of Polishing Rate

The load dependency of the polishing rate was evaluated on the basis of a different in polishing rate between a load of 3.0 psi (low load) and a load of 4.0 psi (high load), that is “4.0 psi value - 3.0 psi value”, by using each CMP polishing liquid mentioned above according to the same procedure as in the aforementioned Experiment A. It is confirmed that in Examples, a large difference in polishing rate (a difference of 6500 Å/min or more) between a time when a load of 4.0 psi is applied and a time when a load of 3.0 psi is applied can be achieved and the non-linear load dependency of the polishing rate can be obtained.

### Evaluation of Polishing Rate Ratio

A blanket wafer having a flat silicon oxide film on the surface thereof and a pattern wafer having a concave-convex shaped silicon oxide film on the surface thereof were polished using each CMP polishing liquid mentioned above under the polishing conditions below to obtain polishing rates. As the blanket wafer, a wafer that has a silicon oxide film having a film thickness of 1000 nm disposed on a silicon substrate having a diameter of 300 mm was used. As the pattern wafer, a wafer, which is obtained by etching a part on a silicon substrate having a diameter of 300 mm at a depth of 3 µm to form a linear concave portion, thereby forming a concavo-convex pattern with Line/Space = 20/80 µm, and then by forming a silicon oxide film having a thickness of 4 µm on the convex portion and in the concave portion, was used.

### Polishing Conditions

Polishing apparatus: Polishing machine for CMP, Reflexion-LK (manufactured by Applied Materials, Inc.)

Polishing pad: Porous urethane pad IC-1010 (manufactured by DuPont)
Polishing pressure (load): 3.0 psi
Number of revolutions of platen: 126 rpm
Number of revolutions of head: 125 rpm
Amount of CMP polishing liquid to be supplied: 250 mL/min
Polishing time: 30 seconds

The polishing rate of the blanket wafer was calculated on the basis of the removal amount of the silicon oxide film and the polishing time in the blanket wafer. The polishing rate of the pattern wafer was calculated on the basis of the removal amount of the convex portion of the silicon oxide film and the polishing time in the pattern wafer. Furthermore, the polishing rate ratio between the pattern wafer and the blanket wafer was calculated. The results are shown in Table 2.

Table 2

| | | Cationic polymer | Cyclic compound | | Polishing rate [Å/min] | | Polishing rate ratio (B/A) |
|---|---|---|---|---|---|---|---|
| | | Content [% by mass] | Type | Content [% by mass] | Blanket wafer (A) | Pattern wafer (B) | |
| Example | B1 | 0.004 | 2-Aminobenzoic acid | 0.2 | 1700 | 22000 | 12.9 |
| | B2 | | | 0.03 | 1900 | 19300 | 10.2 |
| | B3 | | 2-Pyridinecarboxylic acid | 0.2 | 2200 | 20800 | 9.5 |
| | B4 | 0.002 | 3-Pyridinecarboxylic acid | 0.03 | 2800 | 20700 | 7.4 |
| | B5 | 0.004 | 1-(2-Pyridinyl)-1-ethanone | | 1600 | 15400 | 9.6 |
| | B6 | | Pyridine-3-carboxamide | | 2100 | 17300 | 8.2 |
| Comparative Example | B1 | | - | | 800 | 8200 | 10.3 |
| | B2 | - | - | | 8900 | 15700 | 1.8 |
| | B3 | - | 2-Pyridinecarboxylic acid 0.03 | | 9500 | 21200 | 2.2 |

From the results of Table 2, it was shown that, in Examples, as compared to Comparative Examples, the polishing rate of the pattern wafer is as high as 90000 Å/min or more and the polishing rate ratio between the pattern wafer and the blanket wafer is as high as 3.0 or more.

In the present specification, the present inventors or the like have described most preferred modes for carrying out the invention. Favorable modified modes similar to them may also become apparent when a person skilled in the art reads the description described above in some cases. The present inventors or the like are also well aware of performing different modes of the present disclosure and performing inventions of similar mode that apply the core principle of the present disclosure. Furthermore, in the present disclosure, as its principle, all modified modes of the content described in CLAIMS, and any arbitrary combination of various elements described above may be employed. All possible combinations thereof are encompassed by the present disclosure, unless otherwise specified in the present specification or unless specifically negated by context.

### REFERENCE SIGNS LIST

1: silicon substrate, 2: silicon nitride film, 3: silicon oxide film, 5: embedded portion, 100, 200, 300: base substrate, 110, 210, 310: integrated memory cell, 120, 220, 320: insulating member, 120a, 220a, 320a: lower layer part, 120b, 220b, 320b: upper layer part, D: step height.

1. A CMP polishing liquid comprising: abrasive grains; and a cationic polymer, wherein
the cationic polymer has a main chain containing a nitrogen atom and a carbon atom and a hydroxyl group bonded to the carbon atom.

2. The CMP polishing liquid according to claim 1, wherein the cationic polymer includes a plurality of kinds of structure units each having the main chain.

3. The CMP polishing liquid according to claim 1, wherein the cationic polymer contains a reaction product of a raw material containing at least dimethylamine and epichlorohydrin.

4. The CMP polishing liquid according to claim 3, wherein the cationic polymer contains a reaction product of a raw material containing at least dimethylamine, ammonia, and epichlorohydrin.

5. The CMP polishing liquid according to claim 1, wherein a weight average molecular weight of the cationic polymer is 10000 to 1000000.

6. The CMP polishing liquid according to claim 1, wherein a content of the cationic polymer is 0.00001 to 1 part by mass with respect to 100 parts by mass of the CMP polishing liquid.

7. The CMP polishing liquid according to claim 1, wherein the abrasive grains contain a cerium-based compound.

8. The CMP polishing liquid according to claim 7, wherein the cerium-based compound is cerium oxide.

9. The CMP polishing liquid according to claim 1, wherein a content of the abrasive grains is 0.01 to 10 parts by mass with respect to 100 parts by mass of the CMP polishing liquid.

10. The CMP polishing liquid according to claim 1, further comprising at least one cyclic compound selected from the group consisting of an amino group-containing aromatic compound and a nitrogen-containing heterocyclic compound.

11. The CMP polishing liquid according to claim 10, wherein the cyclic compound contains the amino group-containing aromatic compound, and
the amino group-containing aromatic compound contains a compound having an amino group and at least one selected from the group consisting of a carboxy group and a carboxylate group, as a functional group bonded to an aromatic ring.

12. The CMP polishing liquid according to claim 10, wherein the cyclic compound contains the nitrogen-containing heterocyclic compound, and
the nitrogen-containing heterocyclic compound contains a compound having a pyridine ring.

13. The CMP polishing liquid according to claim 12, wherein the nitrogen-containing heterocyclic compound contains at least one selected from the group consisting of pyridinecarboxylic acid, 1-(2-pyridinyl)-1-ethanone, and pyridine-3-carboxamide.

14. The CMP polishing liquid according to claim 10, wherein a content of the cyclic compound is 0.001 to 1 part by mass with respect to 100 parts by mass of the CMP polishing liquid.

15. The CMP polishing liquid according to claim 1, wherein a pH is 8.0 or less.

16. The CMP polishing liquid according to claim 1, wherein a pH is 2.0 to 5.0.

17. The CMP polishing liquid according to claim 1, wherein the CMP polishing liquid is used for polishing an insulating material.

18. The CMP polishing liquid according to claim 17, wherein the insulating material contains silicon oxide.

19. A polishing method comprising a step of polishing a material to be polished by using the CMP polishing liquid according to claim 1.

20. The polishing method according to claim 19, wherein the material to be polished contains silicon oxide.
